(19) United States
(12) Patent Application Publication
(10) Pub. No.: US 2009/0004365 A1
(43) Pub. Date: Jan. 1, 2009

(54) CONTAMINANT-SCAVENGING LAYER ON OLED ANODES

(76) Inventors: Liang-Sheng Liao, Rochester, NY (US); Kevin P. Klubek, West Henrietta, NY (US); Wojciech K. Slusarek, Rochester, NY (US); Tukaram K. Hatwar, Penfield, NY (US)

Correspondence Address: Patent Legal Staff;Eastman Kodak Company, 343 State Street, Rochester, NY, 14650-2201, US

(21) Appl. No.: 12/205,952

(22) Filed: Sep. 8, 2008

Related U.S. Application Data
(62) Division of application No. 11/111,386, filed on Apr. 21, 2005.

(51) Int. Cl. B05D 5/12

(52) U.S. Cl. 427/66

(57) ABSTRACT

An OLED includes an anode formed over a substrate and a contaminant-scavenging layer formed over the anode, wherein the contaminant-scavenging layer includes one or more organic materials but not a hexaazatriphenylene derivative, each having an electron-accepting property and a reduction potential greater than −0.1 V vs. a Saturated Calomel Electrode, and wherein the one or more organic materials provide more than 50% by mole ratio of the contaminant-scavenging layer. The OLED also includes an organic electroluminescent unit formed over the contaminant-scavenging layer, wherein the organic electroluminescent unit includes a hole-transporting layer, a light-emitting layer, and an electron-transporting layer, and a cathode formed over the organic electroluminescent unit.

### CROSS REFERENCE TO RELATED APPLICATIONS

This application is a divisional of commonly-assigned U.S. patent application Ser. No. 11/111,386 filed Apr. 21, 2005. Reference is made to commonly assigned U.S. patent application Ser. No. 11/111,367 filed Apr. 21, 2005 (U.S. Patent Application Publication No. 2006-0240280) by Liang-Sheng Liao et al., entitled “OLED Anode Modification Layer”, the disclosure of which is herein incorporated by reference.

### FIELD OF INVENTION

The present invention relates to reducing contamination on an anode surface in an organic light-emitting device (OLED).

### BACKGROUND OF THE INVENTION

Multiple-layered organic light-emitting devices or organic electroluminescent (EL) devices, as first described by Tang in commonly assigned U.S. Pat. No. 4,356,429, are used as color pixel components in OLED displays and are also used as solid-state lighting sources. OLEDs are also useful for some other applications due to their low drive voltage, high luminance, wide viewing angle, fast signal response time, and simple fabrication process.

A typical OLED includes two electrodes and one organic EL unit disposed between the two electrodes. The organic EL unit commonly includes an organic hole-transporting layer (HTL), organic light-emitting layer (LEL), and an organic electron-transporting layer (ETL). One of the electrodes is the anode, which is capable of injecting positive charges (holes) into the HTL of the EL unit, and the other electrode is the cathode, which is capable of injecting negative charges (electrons) into the ETL of the EL unit. When the OLED is positively biased with certain electrical potential between the two electrodes, holes injected from the anode and electrons injected from the cathode can recombine and emit light from the LEL. Since at least one of the electrodes is optically transmissive, the emitted light can be seen through the transmissive electrode.

In order to fabricate an OLED, there are typically at least two separate processes that are needed. In the first process, the anode is formed on a substrate. For example, a commonly used transparent anode, indium-tin-oxide (ITO) or indium zinc-oxide (IZO), is first formed and patterned on a transparent substrate or a thin film transistor (TFT) backplane by ion sputtering technique. The patterned ITO top surface also needs to be modified as an anode at least by an oxygen treatment, such as oxygen plasma treatment or ultraviolet excited ozone exposure (or UV ozone treatment). In the second process, the rest of the OLED, i.e. an organic EL unit and a cathode, is fabricated on the anode.

Since there is a time lag between the anode surface treatment and the formation of the organic EL unit, the clean anode surface is subject to contamination during ambient storage and transfer from the ambient to a vacuum chamber. Surface contamination cannot be readily avoided even in a vacuum chamber. It is possible to obtain one monolayer of contaminants per second on the surface if the surface were exposed to an environment having a pressure of about 10⁻⁶ Torr, providing the contaminants have a sticking coefficient of 1. Therefore, an anode that isn't contaminated before being transferred into a vacuum chamber will become contaminated when sitting in the vacuum chamber and waiting for the deposition of the organic EL unit on its surface. As a result, the work function of the contaminated anode will be reduced causing an increased hole-injecting barrier at the interface of the anode and the first organic layer formed during the deposition of the organic EL unit. This high injection barrier will further cause high drive voltage and low operational stability in the OLED.

Son et al. in U.S. Pat. No. 6,720,573 discloses hexaazatriphenylene derivative as a p-type semiconducting organic material for use as a hole-injecting layer in OLEDs. Although the hexaazatriphenylene derivative can have scavenging properties, Son et al. did not discover the properties in their invention.

### SUMMARY OF THE INVENTION

It is therefore an object of the present invention to reduce the anode surface contamination effects on the EL performance of an OLED.

This object is achieved by an OLED comprising:

a) an anode formed over a substrate;

b) a contaminant-scavenging layer formed over the anode, wherein the contaminant-scavenging layer includes one or more organic materials but not a hexaazatriphenylene derivative, each having an electron-accepting property and a reduction potential greater than −0.1 V vs. a Saturated Calomel Electrode, and wherein the one or more organic materials provide more than 50% by mole ratio of the contaminant-scavenging layer;

c) an organic electroluminescent unit formed over the contaminant-scavenging layer, wherein the organic electroluminescent unit includes a hole-transporting layer, a light-emitting layer, and an electron-transporting layer; and

d) a cathode formed over the organic electroluminescent unit.

The present invention makes use of a contaminant-scavenging layer on the modified anode surface to effectively oxidize the contaminants and restore the anode to an effective condition. As a result, an anode can be stored either in an ambient or in a vacuum for a reasonably longer time, and a contaminated anode still can be used in OLED fabrication. It is an advantage of the present invention that the OLED with a contaminant-scavenging layer can have a normal initial drive voltage and have improved operational stability. Moreover, use of the contaminant-scavenging layer will permit for OLEDs to have less scattered EL performance because the anode surface condition for all devices will be identical and reproducible, and this can actually improve the production yield and reduce the production cost.

### BRIEF DESCRIPTION OF THE DRAWINGS

FIG. 1 shows a cross-sectional view of a prior art OLED;

FIG. 2 shows a cross-sectional view of another prior art OLED;

FIG. 3 shows a cross-sectional view of one embodiment of an OLED prepared with a contaminant-scavenging layer in contact with the modified anode surface in accordance with the present invention;

FIG. 4 shows a cross-sectional view of another embodiment of an OLED prepared with a contaminant-scavenging layer formed over the modified anode in accordance with the present invention;

FIG. 5 shows a cross-sectional view of one embodiment of an organic electroluminescent unit including a hole-transporting layer, a light-emitting layer, and an electron-transporting layer in accordance with the present invention;

FIG. 6 shows a cross-sectional view of another embodiment of an organic electroluminescent unit including a hole-injecting layer, a hole-transporting layer, a light-emitting layer, and an electron-transporting layer in accordance with the present invention; and

FIG. 7 shows a cross-sectional view of yet another embodiment of an organic electroluminescent unit including a hole-injecting layer, a hole-transporting layer, a light-emitting layer, an electron-transporting layer, and an electron-injecting layer in accordance with the present invention.

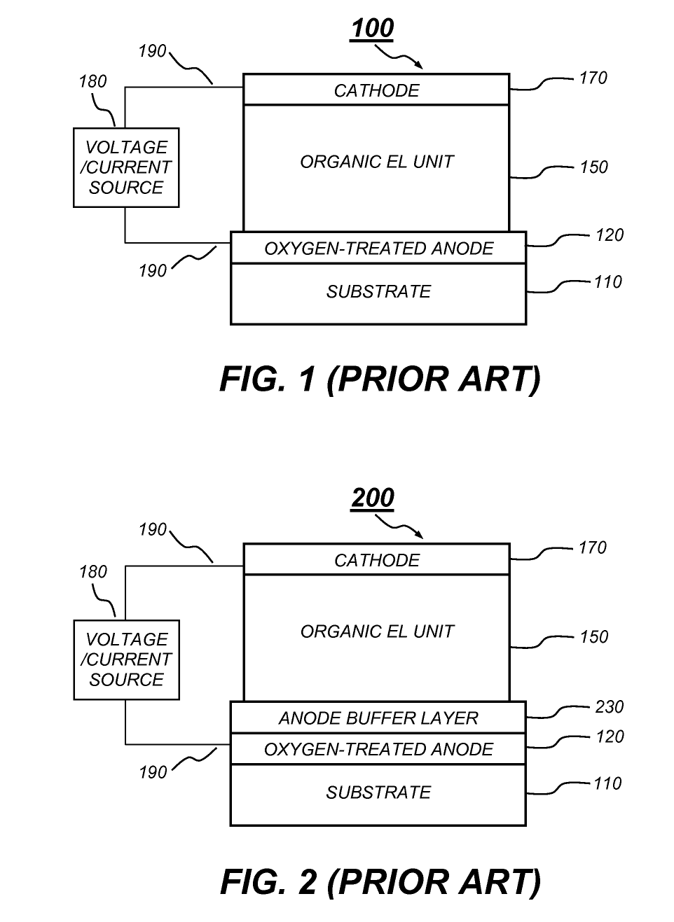

It will be understood that FIGS. 1-7 are not to scale since the individual layers are too thin and the thickness differences of various layers are too great to permit depiction to scale.

### DETAILED DESCRIPTION OF THE INVENTION

There is shown a cross-sectional view of a prior art OLED in FIG. 1. OLED 100 includes substrate 110, oxygen-treated anode 120, organic EL unit 150, and cathode 170. OLED 100 is externally connected to a voltage/current source 180 through electrical conductors 190. OLED 100 is operated by applying an electric potential produced by the voltage/current source 180 between the pair of contact electrodes, anode 120 and cathode 170. There is also shown a cross-sectional view of another prior art OLED in FIG. 2. OLED 200 in FIG. 2 is the same as OLED 100 in FIG. 1 except that there is an anode buffer layer 230 disposed between the oxygen-treated anode 120 and the organic EL unit 150.

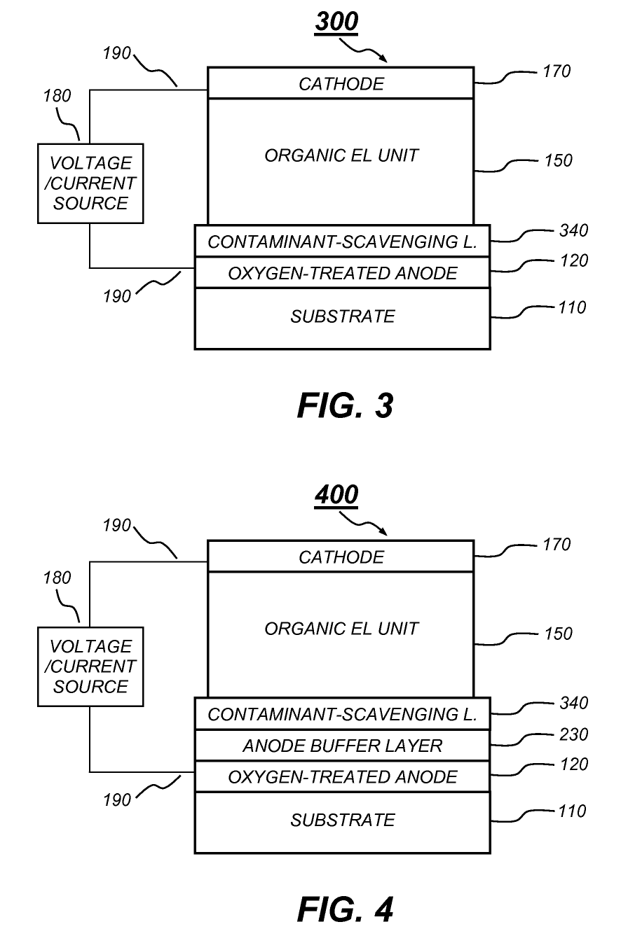

Turning to FIG. 3, there is shown a cross-sectional view of one embodiment of an OLED with a contaminant-scavenging layer 340 over the oxygen-treated anode 120 in accordance with the present invention. Turning to FIG. 4, there is also shown a cross-sectional view of another embodiment of an OLED with a contaminant-scavenging layer 340 over the anode buffer layer 230 in accordance with the present invention. OLED 300 in FIG. 3 and OLED 400 in FIG. 4 are the same as OLED 100 in FIG. 1 and OLED 200 in FIG. 2, respectively, except that a contaminant-scavenging layer 340 (denoted as “CONTAMINANT-SCAVENGING L.” in the figures) is added into each of the devices in FIGS. 3 and 4.

Substrate 110, as shown in FIGS. 1, 2, 3 and 4, can be an organic solid, an inorganic solid, or includes organic and inorganic solids that provide a supporting backplane to hold the OLED. Substrate 110 can be rigid or flexible and can be processed as separate individual pieces, such as sheets or wafers, or as a continuous roll. Typical substrate materials include glass, plastic, metal, ceramic, semiconductor, metal oxide, semiconductor oxide, or semiconductor nitride, or combinations thereof. Substrate 110 can be a homogeneous mixture of materials, a composite of materials, or multiple layers of materials. Substrate 110 can also be a backplane containing TFT circuitry commonly used for preparing OLED display, e.g. an active-matrix low-temperature poly-silicon TFT substrate. The substrate 110 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing or light reflective. Substrates for use in the present invention include, but are not limited to, glass, plastic, semiconductor materials, ceramics, and circuit board materials, or any others commonly used in the formation of OLEDs, which can be either passive-matrix devices or active-matrix devices.

An oxygen-treated anode 120, as shown in FIGS. 1, 2, 3 and 4, is formed over substrate 110. When EL emission is viewed through the substrate 110, the anode should be transparent or substantially transparent to the emission of interest. Common transparent anode materials useful in the present invention are indium-tin oxide and tin oxide, other metal oxides can also work including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material. For applications where EL emission is viewed through the top electrode, the transmissive characteristics of the anode material are immaterial and any conductive material can be used, regardless if it is transparent, opaque, or reflective. Example conductors for this application include, but are not limited to, gold, silver, copper, iridium, palladium, and platinum. Desired anode materials can be deposited by any suitable way such as evaporation, sputtering, chemical vapor deposition, or electrochemical means. Anode materials can be patterned using well known photolithographic processes. An untreated anode or a patterned anode typically cannot be used as an effective anode for OLED. The anode surface needs to be modified to become a high work function surface before the formation of organic EL unit on the surface. A common way to modify the anode surface is oxygen treatment, such as oxygen plasma treatment or UV ozone treatment. Therefore, in a real device fabrication, the anode used for OLED is typically an oxygen-treated anode.

Another way to modify the anode surface is to form an anode buffer layer 230 over an oxygen-treated anode 120 as shown in FIGS. 2 and 4, or over an as-prepared anode in an OLED (not shown in the figures). The anode buffer layer can serve to facilitate hole injection from the anode into the organic EL unit and to improve the film formation property of subsequent organic layers. The anode buffer layer typically has a thickness less than 5 nm. Suitable materials for use in the anode buffer layer 230 include, but are not limited to, plasma-deposited fluorocarbon polymers (denoted as CFₓ) as described in U.S. Pat. No. 6,208,075. Alternative materials for use in the anode buffer layer 230 include inorganic compounds as described in U.S. Patent Application Publication 2004/0113547 A1. These inorganic compounds include aluminum oxide, titanium oxide, zinc oxide, ruthenium oxide, nickel oxide, zirconium oxide, tantalum oxide, magnesium oxide, calcium oxide, strontium oxide, vanadium oxide, yttrium oxide, lithium oxide, cesium oxide, chromium oxide, silicon oxide, barium oxide, manganese oxide, cobalt oxide, copper oxide, praseodymium oxide, tungsten oxide, germanium oxide, potassium oxide, alkali metal fluorides, and other compounds.

Organic EL unit 150, as shown in FIGS. 1, 2, 3 and 4, is capable of supporting hole injection, hole transport, electron injection, electron transport, and electron-hole recombination to produce light. Organic EL unit 150 includes a plurality of layers. Such layers can include a hole-injecting layer (HIL), a hole-transporting layer (HTL), a light-emitting layer (LEL), an electron-transporting layer (ETL), an electron-injecting layer (EIL), hole-blocking layer (HBL), electron-blocking layer (EBL), an exciton-blocking layer (XBL), and others known in the art. Various layers can serve multiple functions (e.g., an ETL can also serve as an HBL), and there can be multiple layers that have a similar function (e.g., there can be several LELs and ETLs). There are many organic EL multilayer structures known in the art that can be used as EL units of the present invention. Some non-limiting examples include, HTL/LEL(s)/ETL, HTL/LEL(s)/EIL, HIL/HTL/LEL(s)/ETL, HIL/HTL/LEL(s)/ETL/EIL, HIL/HTL/EBL or XBL/LEL(s)/ETL/EIL, HIL/HTL/LEL(s)/HBL/ETL/EIL. Preferably, the layer structure of the EL unit is of HTL/LEL(s)/ETL, HIL/HTL/LEL(s)/ETL, or HIL/HTL/LEL(s)/ETL/EIL. Considering the number of the LELs within an organic EL unit 150, the number of LELs in the EL unit can be changed typically from 1 to 3.

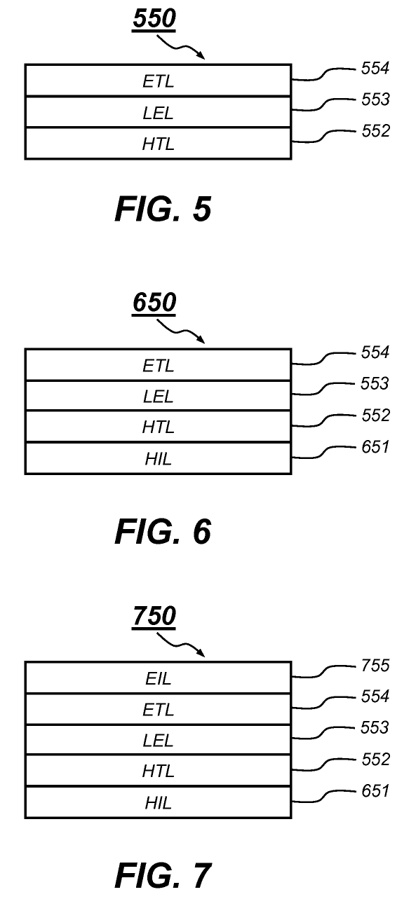

Shown in FIGS. 5, 6, and 7 are exemplary embodiments of organic EL units used in OLEDs in the present invention. Organic EL unit 550 in FIG. 5 includes HTL 552, LEL 553, and ETL 554. Organic EL unit 650 in FIG. 6 includes HIL 651, HTL 552, LEL 553, and ETL 554. Organic EL unit 750 in FIG. 7 includes HIL 651, HTL 552, LEL 553, ETL 554, and EIL 755.

Although not always necessary, it is often useful to provide an HIL in the organic EL unit. HIL 651 in the organic EL units as shown in FIGS. 6 and 7 can serve to facilitate hole injection from the anode into the HTL, thereby reducing the drive voltage of the OLEDs. Suitable materials for use in HIL 651 include, but are not limited to, porphyrinic compounds as described in U.S. Pat. No. 4,720,432 and some aromatic amines, for example, m-MTDATA (4,4′,4″-tris[(3-ethylphenyl)phenylamino]triphenylamine). Alternative hole-injecting materials reportedly useful in organic EL devices are described in EP 0 891 121 A1 and EP 1 029 909 A1. In addition, a p-type doped organic layer is also useful for the HIL as described in U.S. Pat. No. 6,423,429. The term “p-type doped organic layer” means that this layer has semiconducting properties after doping, and the electrical current through this layer is substantially carried by the holes. The conductivity is provided by the formation of a charge-transfer complex as a result of hole transfer from the dopant to the host material.

The HTL 552 in the organic EL units as shown in FIGS. 5, 6, and 7 contains at least one hole-transporting material such as an aromatic tertiary amine, where the aromatic tertiary amine is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals or at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described VanSlyke in U.S. Pat. No. 4,720,432 and VanSlyke et al. in U.S. Pat. No. 5,061,569. The HTL can be formed of a single or a mixture of aromatic tertiary amine compounds. Illustrative of useful aromatic tertiary amines are the following:
1,1-Bis(4-di-p-tolylaminophenyl)cyclohexane;
1,1-Bis(4-di-p-tolylaminophenyl)-4-phenylcyclohexane;
N,N,N′,N′-tetraphenyl-4,4′″-diamino-1,1′:4′,1″:4″,1′″-quaterphenyl;
Bis(4-dimethylamino-2-methylphenyl)phenylmethane;
1,4-bis[2-[4-[N,N-di(p-toly)amino]phenyl]vinyl]benzene (BDTAPVB);
N,N,N′,N′-Tetra-p-tolyl-4,4′-diaminobiphenyl;
N,N,N′,N′-Tetraphenyl-4,4′-diaminobiphenyl;
N,N,N′,N′-tetra-1-naphthyl-4,4′-diaminobiphenyl;
N,N,N′,N′-tetra-2-naphthyl-4,4′-diaminobiphenyl;
N-Phenylcarbazole;
4,4′-Bis[N-(1-naphthyl)-N-phenylamino]biphenyl (NPB);
4,4′-Bis[N-(1-naphthyl)-N-(2-naphthyl)amino]biphenyl (TNB);
4,4′-Bis[N-(1-naphthyl)-N-phenylamino]p-terphenyl;
4,4′-Bis[N-(2-naphthyl)-N-phenylamino]biphenyl;
4,4′-Bis[N-(3-acenaphthenyl)-N-phenylamino]biphenyl;
1,5-Bis[N-(1-naphthyl)-N-phenylamino]naphthalene;
4,4′-Bis[N-(9-anthryl)-N-phenylamino]biphenyl;
4,4′-Bis[N-(1-anthryl)-N-phenylamino]-p-terphenyl;
4,4′-Bis[N-(2-phenanthryl)-N-phenylamino]biphenyl;
4,4′-Bis[N-(8-fluoranthenyl)-N-phenylamino]biphenyl;
4,4′-Bis[N-(2-pyrenyl)-N-phenylamino]biphenyl;
4,4′-Bis[N-(2-naphthacenyl)-N-phenylamino]biphenyl;
4,4′-Bis[N-(2-perylenyl)-N-phenylamino]biphenyl;
4,4′-Bis[N-(1-coronenyl)-N-phenylamino]biphenyl;
2,6-Bis(di-p-tolylamino)naphthalene;
2,6-Bis[di-(1-naphthyl)amino]naphthalene;
2,6-Bis[N-(1-naphthyl)-N-(2-naphthyl)amino]naphthalene;
N,N,N′,N′-Tetra(2-naphthyl)-4,4″-diamino-p-terphenyl;
4,4′-Bis {N-phenyl-N-[4-(1-naphthyl)-phenyl]amino}biphenyl;
2,6-Bis[N,N-di(2-naphthyl)amino]fluorene;
4,4′,4″-tris[(3-methylphenyl)phenylamino]triphenylamine (MTDATA); and
4,4′-Bis[N-(3-methylphenyl)-N-phenylamino]biphenyl (TPD).

Another class of useful hole-transporting materials includes polycyclic aromatic compounds as described in EP 1 009 041. Tertiary aromatic amines with more than two amino groups can be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

The LEL 553 in the organic EL units as shown in FIGS. 5, 6, and 7 can include a luminescent fluorescent or phosphorescent material where electroluminescence is produced as a result of electron-hole pair recombination in this region. The light-emitting layer can be comprised of a single material, but more commonly contains at least one host material doped with at least one guest emitting material or materials where light emission comes primarily from the emitting materials and can be of any color. This guest emitting material is often referred to as a light emitting dopant. The host materials in the light-emitting layer can be an electron-transporting material, as defined below, a hole-transporting material, as defined above, or another material or combination of materials that support hole-electron recombination. The emitting material is typically chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small nonpolymeric molecules or polymeric materials including polyfluorenes and polyvinylarylenes, e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing an emitting material is a comparison of the electron energy bandgap, which is defined as the energy difference between the highest occupied molecular orbital and the lowest unoccupied molecular orbital of the molecule. For efficient energy transfer from the host to the emitting material, a necessary condition is that the bandgap of the dopant is smaller than that of the host material. For phosphorescent emitters (including materials that emit from a triplet excited state, i.e., so-called “triplet emitters”) it is also important that the triplet energy level of the host be high enough to enable energy transfer from host to emitting material.

Host and emitting materials known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6,534,199, 6,661,023, U.S. Patent Application Publications 2002/0127427 A1, 2003/0198829 A1, 2003/0203234 A1, 2003/0224202 A1, and 2004/0001969 A1.

Metal complexes of 8-hydroxyquinoline (oxine) and similar derivatives constitute one class of useful host compounds capable of supporting electroluminescence. Illustrative of useful chelated oxinoid compounds are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo {f}-8-quinolinolato]zinc (II);

CO-4: Bis(2-methyl-8-quinolinolato)aluminum(III)-μ-oxo-bis(2-methyl-8-quinolinolato) aluminum(III);

CO-5: Indium trisoxine [alias, tris(8-quinolinolato)indium];

CO-6: Aluminum tris(5-methyloxine) [alias, tris(5-methyl-8-quinolinolato) aluminum(III)];

CO-7: Lithium oxine [alias, (8-quinolinolato)lithium(I)];

CO-8: Gallium oxine [alias, tris(8-quinolinolato)gallium(III)]; and

CO-9: Zirconium oxine [alias, tetra(8-quinolinolato)zirconium(IV)].

Another class of useful host materials includes derivatives of anthracene, such as those described in U.S. Pat. Nos. 5,935,721, 5,972,247, 6,465,115, 6,534,199, 6,713,192, U.S. Patent Application Publications 2002/0048687 A1, 2003/0072966 A1, and WO 2004/018587. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrylium and thiapyrylium compounds, fluorene derivatives, periflanthene derivatives, indenoperylene derivatives, bis(azinyl)amine boron compounds, bis(azinyl)methane boron compounds, derivatives of distryrylbenzene and distyrylbiphenyl, and carbostyryl compounds. Among derivatives of distyrylbenzene, particularly useful are those substituted with diarylamino groups, informally known as distyrylamines.

Suitable host materials for phosphorescent emitters should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2, WO 01/39234 A2, WO 01/93642 A1, WO 02/074015 A2, WO 02/15645 A1, and U.S. Patent Application Publication 2002/0117662 A1. Suitable hosts include certain aryl amines, triazoles, indoles and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinylcarbazole), including their derivatives.

Examples of useful phosphorescent dopants that can be used in light-emitting layers of this invention include, but are not limited to, those described in WO 00/57676, WO 00/70655, WO 01/41512 A1, WO 02/15645 A1, WO 01/93642 A1, WO 01/39234 A2, WO 02/074015 A2, WO 02/071813 A1, U.S. Pat. Nos. 6,458,475, 6,573,651, 6,413,656, 6,515,298, 6,451,415, 6,097,147, 6,451,455, U.S. Patent Application Publications 2003/0017361 A1, 2002/0197511 A1, 2003/0072964 A1, 2003/0068528 A1, 2003/0124381 A1, 2003/0059646 A1, 2003/0054198 A1, 2002/0100906 A1, 2003/0068526 A1, 2003/0068535 A1, 2003/0141809 A1, 2003/0040627 A1, 2002/0121638 A1, EP 1 239 526 A2, EP 1 238 981 A2, EP 1 244 155 A2, JP 2003-073387, JP 2003-073388, JP 2003-059667, and JP 2003-073665. Preferably, useful phosphorescent dopants include transition metal complexes, such as iridium and platinum complexes.

In some cases it is useful for one or more of the LELs within an EL unit to emit broadband light, for example white light. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,182, 6,627,333, 6,696,177, 6,720,092, and U.S. Patent Application Publications 2002/0186214 A1, 2002/0025419 A1, and 2004/0009367 A1. In some of these systems, the host for one light-emitting layer is a hole-transporting material.

Preferred organic materials for use in forming the ETL 554 in the organic EL units as shown in FIGS. 5, 6, and 7 are metal chelated oxinoid compounds, including chelates of oxine itself, also commonly referred to as 8-quinolinol or 8-hydroxyquinoline. Such compounds help to inject and transport electrons, exhibit high levels of performance, and are readily deposited to form thin films. Exemplary oxinoid compounds have been listed above from CO-1 to CO-9. (The oxinoid compounds can be used as both the host material in LEL 553 and the electron-transporting material in ETL 554).

Other electron-transporting materials include various butadiene derivatives as disclosed in U.S. Pat. No. 4,356,429 and various heterocyclic optical brighteners as described in U.S. Pat. No. 4,539,507. Benzazoles, oxadiazoles, triazoles, pyridinethiadiazoles, triazines, phenanthroline derivatives, and some silole derivatives are also useful electron-transporting materials.

The EIL 755 in organic EL unit 750 as shown in FIG. 7 is an n-type doped layer containing at least one electron-transporting material as a host material and at least one n-type dopant (This EIL can also be called an n-type doped EIL 755). The term “n-type doped layer” means that this layer has semiconducting properties after doping, and the electrical current through this layer is substantially carried by the electrons. The host material is capable of supporting electron injection and electron transport. The electron-transporting materials used in ETL 554 represent a useful class of host materials for the n-type doped EIL 755. Preferred materials are metal chelated oxinoid compounds, including chelates of oxine itself (also commonly referred to as 8-quinolinol or 8-hydroxyquinoline), such as tris(8-hydroxyquinoline)aluminum (Alq). Other materials include various butadiene derivatives as disclosed by Tang in U.S. Pat. No. 4,356,429, various heterocyclic optical brighteners as disclosed by Van Slyke and Tang et al. in U.S. Pat. No. 4,539,507, triazines, hydroxyquinoline derivatives, benzazole derivatives, and phenanthroline derivatives. Silole derivatives, such as 2,5-bis(2′,2″-bipridin-6-yl)-1,1-dimethyl-3,4-diphenyl silacyclopentadiene are also useful host organic materials. The combination of the aforementioned host materials is also useful to form the n-typed doped EIL 755. More preferably, the host material in the n-type doped EIL 755 includes Alq, 4,7-diphenyl-1,10-phenanthroline (Bphen), 2,9-dimethyl-4,7-diphenyl-1,10-phenanthroline (BCP), or 2,2′-[1,1′-biphenyl]-4,4′-diylbis[4,6-(p-tolyl)-1,3,5-triazine] (TRAZ), or combinations thereof.

Both EIL 755 and ETL 554 in the EL units in the OLEDs can use the same or different material.

The n-type dopant in the n-type doped EIL 755 includes alkali metals, alkali metal compounds, alkaline earth metals, or alkaline earth metal compounds, or combinations thereof. The term “metal compounds” includes organometallic complexes, metal-organic salts, and inorganic salts, oxides and halides. Among the class of metal-containing n-type dopants, Li, Na, K, Rb, Cs, Mg, Ca, Sr, Ba, La, Ce, Sm, Eu, Tb, Dy, or Yb, and their compounds, are particularly useful. The materials used as the n-type dopants in the n-type doped EIL 325 also include organic reducing agents with strong electron-donating properties. By “strong electron-donating properties” it is meant that the organic dopant should be able to donate at least some electronic charge to the host to form a charge-transfer complex with the host. Non-limiting examples of organic molecules include bis(ethylenedithio)-tetrathiafulvalene (BEDT-TTF), tetrathiafulvalene (TTF), and their derivatives. In the case of polymeric hosts, the dopant can be any of the above or also a material molecularly dispersed or copolymerized with the host as a minor component. Preferably, the n-type dopant in the n-type doped EIL 755 includes Li, Na, K, Rb, Cs, Mg, Ca, Sr, Ba, La, Ce, Nd, Sm, Eu, Tb, Dy, or Yb, or combinations thereof. The n-type doped concentration is preferably in the range of 0.01-20% by volume. The thickness of the n-type doped EIL 755 is typically less than 200 nm, and preferably in the range of less than 150 nm.

Additional layers such as electron or hole-blocking layers can be employed in the organic EL units in the OLEDs. Hole-blocking layers are commonly used to improve efficiency of phosphorescent emitter devices, for example, as in U.S. Patent Application Publication 2002/0015859 A1.

In some instances, LEL 553 and ETL 554 in the organic EL units can optionally be collapsed into a single layer that serves the function of supporting both light emission and electron transportation. It is also known in the art that emitting dopants can be added to the HTL 552, thereby enabling HTL 552 to serve as a host. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in U.S. Patent Application Publication 2002/0025419 A1; U.S. Pat. Nos. 5,683,823, 5,503,910, 5,405,709, 5,283,182, EP 1 187 235, and EP 1 182 244.

Each of the layers in the organic EL unit 150 as shown in FIGS. 1, 2, 3, and 4 can be formed from small molecule (or nonpolymeric) materials (including fluorescent materials and phosphorescent materials), polymeric LED materials, or inorganic materials, or combinations thereof.

The organic materials in the organic EL unit 150 mentioned above are suitably deposited through a vapor-phase method such as thermal evaporation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by thermal evaporation can be vaporized from an evaporation “boat” often comprised of a tantalum material, e.g., as described in U.S. Pat. No. 6,237,529, or can be first coated onto a donor sheet and then sublimed in closer proximity to the substrate. Layers with a mixture of materials can use separate evaporation boats or the materials can be premixed and coated from a single boat or donor sheet. For full color display, the pixelation of LELs can be needed. This pixelated deposition of LELs can be achieved using shadow masks, integral shadow masks, U.S. Pat. No. 5,294,870, spatially defined thermal dye transfer from a donor sheet, U.S. Pat. Nos. 5,688,551, 5,851,709, and 6,066,357, and inkjet method, U.S. Pat. No. 6,066,357. For other organic layers either in the organic EL units or in the intermediate connectors, pixelated deposition is not necessarily needed.

When light emission is viewed solely through the anode, the cathode 170 as shown in FIGS. 1, 2, 3, and 4 can be comprised of nearly any conductive material. Desirable materials have effective film-forming properties to ensure effective contact with the underlying organic layer, promote electron injection at low voltage, and have effective stability. Useful cathode materials often contain a low work-function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bilayers comprising a thin inorganic EIL (or cathode buffer layer) in contact with an organic layer (e.g., ETL or organic EIL), which is capped with a thicker layer of a conductive metal. Here, the inorganic EIL preferably includes a low work-function metal or metal salt and, if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

When light emission is viewed through the cathode, the cathode should be transparent or nearly transparent. For such applications, metals should be thin or one should use transparent conductive oxides, or include these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, and EP 1 076 368. Cathode materials are typically deposited by thermal evaporation, electron beam evaporation, ion sputtering, or chemical vapor deposition. When needed, patterning can be achieved through many well known methods including, but not limited to, through-mask deposition, integral shadow masking, for example as described in U.S. Pat. No. 5,276,380 and EP 0 732 868, laser ablation, and selective chemical vapor deposition.

Most OLEDs are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

The contaminant-scavenging layer 340 in the OLEDs 300 and 400 as shown in FIGS. 3 and 4 is a unique layer in accordance with the present invention. The contaminant-scavenging layer 340 is formed either in contact with the oxygen-treated anode 120 as shown in FIG. 3 or in contact with the anode buffer layer 230 as shown in FIG. 4. As mentioned before, the top surface of the anode has been modified at least by an oxygen treatment or by depositing an anode buffer layer on the surface. The contaminant-scavenging layer includes one or more materials, each having an electron-accepting property and a reduction potential greater than −0.1 V vs. a Saturated Calomel Electrode. Preferably, each of the materials has a reduction potential greater than 0.5 V vs. a Saturated Calomel Electrode. The one or more organic materials constitute more than 50% by mole ratio of the contaminant-scavenging layer.

By “electron-accepting property” it is meant that the organic material has the capability or tendency to accept at least some electronic charge from other types of material that it is adjacent to. Having electron-accepting property also means having a strong oxidizing property. The term “reduction potential”, expressed in volts, measures the affinity of a substance for an electron: the higher the positive number the greater the affinity. Reduction of hydronium ions into hydrogen gas would have a reduction potential of 0.00 V under standard conditions. The reduction potential of a substance can be conveniently obtained by cyclic voltammetry (CV) and it is measured vs. SCE. The measurement of the reduction potential of a substance can be as following: A Model CHI660 electrochemical analyzer (CH Instruments, Inc., Austin, Tex.) is employed to carry out the electrochemical measurements. Both CV and Osteryoung square-wave voltammetry (SWV) can be used to characterize the redox properties of the substance. A glassy carbon (GC) disk electrode (A=0.071 cm²) is used as working electrode. The GC electrode is polished with 0.05 μm alumina slurry, followed by sonication cleaning in deionized water twice and rinsed with acetone between the two water cleanings. The electrode is finally cleaned and activated by electrochemical treatment prior to use. A platinum wire can be used as the counter electrode and the SCE is used as a quasi-reference electrode to complete a standard 3-electrode electrochemical cell. A mixture of acetonitrile and toluene (1:1 MeCN/toluene) or methylene chloride (MeCl₂) can be used as organic solvent systems. All solvents used are ultra low water grade (<10 ppm water). The supporting electrolyte, tetrabutylammonium tetrafluoroborate (TBAF) is recrystallized twice in isopropanol and dried under vacuum for three days. Ferrocene (Fc) can be used as an internal standard (E^{red}_{Fc}=0.50 V vs. SCE in 1:1 MeCN/toluene, E^{red}_{Fc}=0.55 V vs. SCE in MeCl₂, 0.1 M TBAF). The testing solution is purged with high purity nitrogen gas for approximately 15 minutes to remove oxygen and a nitrogen blanket is kept on the top of the solution during the course of the experiments. All measurements are performed at an ambient temperature of 25±1° C. If the compound of interest has insufficient solubility, other solvents can be selected and used by those skilled in the art. Alternatively, if a suitable solvent system cannot be identified, the electron-accepting material can be deposited onto the electrode and the reduction potential of the modified electrode can be measured.

The anode surface is very sensitive to contamination. A few monolayers' contaminants on this surface can reduce the work function of the anode resulting in an increased barrier for hole injection from the anode into the organic EL unit and resulting in an increased drive voltage and reduced operational stability. As is mentioned before, surface contamination cannot be readily avoided even in a vacuum chamber. It is possible to obtain one monolayer of contaminants per second on the surface if the surface were exposed to an environment with a pressure of about 10⁻⁶ Torr, providing the contaminants have a sticking coefficient of 1. Therefore, an uncontaminated anode that is transferred into a vacuum chamber will become contaminated when sitting in the vacuum chamber and waiting for the deposition of the organic EL unit on its surface. Practically, if an anode has been placed in a vacuum chamber or in an inert atmosphere environment for more than 30 min, it is possible for its anode surface to obtain a contamination level at which the drive voltage of an OLED can be affected. Since the material of the contaminant-scavenging layer 340 is a strong oxidizing agent, it can effectively oxidize the surface contaminants by accepting charges from the contaminants, and can effectively convert the contaminants into hole-conducting species. Therefore, by using this contaminant-scavenging layer, the anode surface can maintain a high work function and form a effective interface with the contaminant-scavenging layer without producing a hole-injection barrier. If there were no contamination on the anode surface, this so-called contaminant-scavenging layer can still act as an extra HIL to provide improved hole injection from the anode into the organic EL unit in the OLED. Since this contaminant-scavenging layer is used to react with the surface contaminants and to cure the contaminated anode surface, it can be as thin as 0.1 nm. However, it can also be as thick as 100 nm. Preferably, the thickness of the contaminant-scavenging layer is in the range of from 0.1 to 10 nm. More preferably, the thickness of the contaminant-scavenging layer is in the range of from 0.5 to 5 nm.

It should be noted that if the organic material having a reduction potential higher than −0.1 V vs. SCE is used as a dopant and a hole-transport material is used as a host to form the contaminant-scavenging layer, the dopant molecules will not have the oxidizing capability to effectively oxidize the surface contaminants because during the co-evaporation of the dopant and the host materials, the dopant molecules have already accepted some electron charges from the host molecules to form charge-transfer complexes. This layer can only be used as an HIL. For example, if 2,3,5,6-tetrafluoro-7,7,8,8-tetracyano-quinodimethane (F₄-TCNQ, will be discussed later) is used as a dopant to dope into a host-transporting material, F₄-TCNQ will form a complex with the host molecule and no longer have the capability to oxidize the contaminants on the anode surface.

Several types of organic materials having a reduction potential greater than −0.1 V vs. SCE can be used to form the contaminant-scavenging layer 340 in the present invention. Those materials include, but are not limited to, derivatives of tetracyanoquinodimethane and hexaazatriphenylene.

The organic material used in the contaminant-scavenging layer can be a chemical compound of Formula I (2,3,5,6-tetrafluoro-7,7,8,8-tetracyanoquinodimethane (F₄-TCNQ))

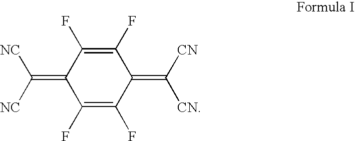

The organic material used in the contaminant-scavenging layer can also be a chemical compound of Formula II

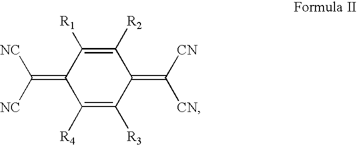

wherein R₁-R₄ represent hydrogen or substituents independently selected from the group including nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, or R₃ and R₄, combine form a ring structure including an aromatic ring, a heteroaromatic ring, or a non-aromatic ring, and each ring is substituted or unsubstituted.

Specifically, the organic material used in the contaminant-scavenging layer can be a chemical compound of Formula IIa

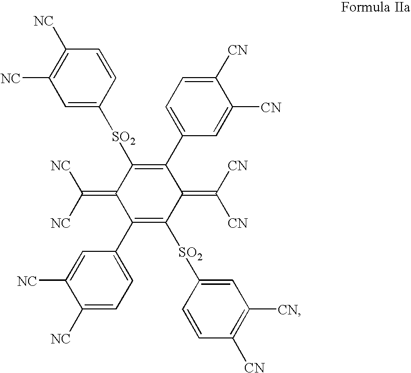

or can be a chemical compound of Formula IIb

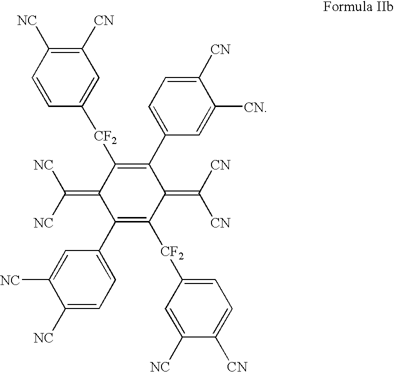

The organic material used in the contaminant-scavenging layer can also be a chemical compound of Formula III

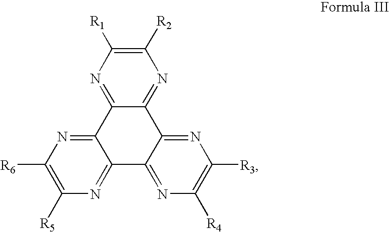

wherein R₁-R₆ represent hydrogen or a substituent independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a non-aromatic ring, and each ring is substituted or unsubstituted.

Specifically, the organic material used in the contaminant-scavenging layer can be a chemical compound of Formula IIIa (hexanitrile hexaazatriphenylene)

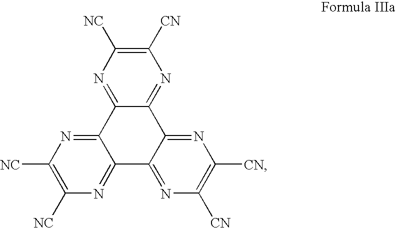

or can be a chemical compound of Formula IIIb

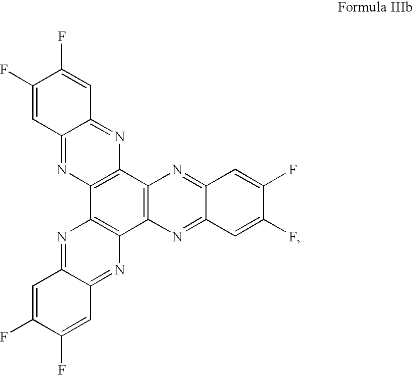

or can be a chemical compound of Formula IIIc

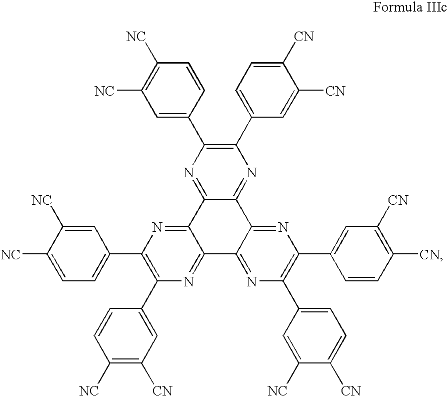

or can be a chemical compound of Formula IIId

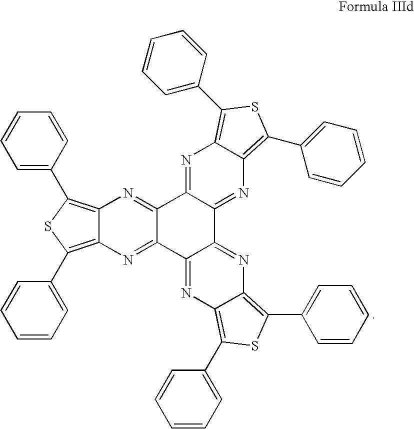

It should also be noted that organic materials suitable for use in the contaminant-scavenging layer not only include the compounds containing at least carbon and hydrogen, but also include metal complexes, e.g., transition metal complexes having organic ligands and organometallic compounds, as long as their reduction potentials are more positive than −0.1 V vs. SCE.

The organic materials used to form the contaminant-scavenging layer 340 are suitably deposited through a vapor-phase method such as thermal evaporation, but can be deposited from a fluid, for example, from a solvent with an optional binder to improve film formation. If the material is a polymer, solvent deposition is useful but other methods can be used, such as sputtering or thermal transfer from a donor sheet. Preferably, the organic materials used to form the contaminant-scavenging layer 340 are deposited by thermal evaporation under reduced pressure.

### EXAMPLES

The following examples are presented for a further understanding of the present invention. In the following examples, the reduction potential of the materials were measured using a Model CHI660 electrochemical analyzer (CH Instruments, Inc., Austin, Tex.) with the method as discussed before. During the fabrication of OLEDs, the thickness of the organic layers and the doping concentrations were controlled and measured in situ using calibrated thickness monitors (INFICON IC/5 Deposition Controller). The EL characteristics of all the fabricated devices were evaluated using a constant current source (KEITHLEY 2400 SourceMeter) and a photometer (PHOTO RESEARCH SpectraScan PR 650) at room temperature. Operational stabilities of the devices were tested at 20 mA/cm² and at 70° C. or at room temperature, or were tested at 80 mA/cm² at room temperature.

### Example 1

### Comparative

The preparation of a conventional OLED is as follows:

A˜1.1 mm thick glass substrate coated with a transparent indium-tin-oxide (ITO) conductive layer was cleaned and dried using a commercial glass scrubber tool. The thickness of ITO is about 42 nm and the sheet resistance of the ITO is about 68 Ω/square. The ITO surface was subsequently treated with oxygen plasma to modify the surface as an anode. A layer of CFx, 1 nm thick, was deposited on the clean ITO surface as the anode buffer layer by decomposing CHF₃ gas in an RF plasma treatment chamber. The substrate was then transferred into a vacuum deposition chamber to wait for deposition of all other layers on top of the substrate. In order to investigate the contamination effect in the vacuum, the substrate waiting time (defined as a duration from transferring the substrate into the vacuum chamber to starting the deposition of the first layer of the organic EL unit onto the substrate in the chamber) is set to about 60 hours. After the waiting period, the following layers were deposited in the following sequence by evaporation from a heated boat under a vacuum of approximately 10⁻⁶ Torr:

### 1. EL Unit:

a) an HTL, 75 nm thick, including “4,4′-bis[N-(1-naphthyl)-N-phenylamino]biphenyl” (NPB);

b) a LEL, 30 nm thick, including “tris(8-hydroxyquinoline)-aluminum” (Alq); and

c) an ETL, 30 nm thick, including Alq.

2. Cathode: approximately 210 nm thick, including Mg:Ag (formed by co-evaporation of about 95 vol. % Mg and 5 vol. % Ag)

After the deposition of these layers, the device was transferred from the deposition chamber into a dry box (VAC Vacuum Atmosphere Company) for encapsulation. The OLED has an emission area of 10 mm².

This conventional OLED with substrate waiting time of 60 hours requires a drive voltage of about 15.3 V to pass 20 mA/cm². Under this test condition, the device has a luminance of 667 cd/m², and a luminous efficiency of about 3.3 cd/A. Its emission peak is at 528 nm. The operational stability was measured as T₈₀(70° C.@20 mA/cm²) (i.e. a time at which the luminance retains 80% of its initial value after being operated at 70° C. and at 20 mA/cm²). Its T₈₀(70° C.@20 mA/cm²) is about 82 hours. The EL performance data are summarized in Table 1.

### Example 2

### Comparative

Another conventional OLED was constructed as the same as that in Example 1, except that the substrate waiting time was changed from 60 hours to 22 hours.

This conventional OLED requires a drive voltage of about 10.1 V to pass 20 mA/cm². Under this test condition, the device has a luminance of 605 cd/m², and a luminous efficiency of about 3.0 cd/A. Its emission peak is at 528 nm. The operational stability was measured as T₈₀(70° C.@20 mA/cm²) which is about 137 hours. The EL performance data are summarized in Table 1.

### Example 3

### Comparative

Another conventional OLED was constructed as the same as that in Example 1, except that the substrate waiting time was changed from 60 hours to 0.5 hours.

This conventional OLED requires a drive voltage of about 7.3 V to pass 20 mA/cm². Under this test condition, the device has a luminance of 569 cd/m², and a luminous efficiency of about 2.9 cd/A. Its emission peak is at 524 nm. The operational stability was measured as T₈₀(70° C.@20 mA/cm²) which is about 203 hours. This device in Example 3 is a typical device of this kind with normal EL performance. The EL performance data are summarized in Table 1.

Shown in Table 1 is the summary of the EL performance of Examples 1-3 discussed above.

TABLE 1

| | | | | | | T₈₀(70° C. |
|---|---|---|---|---|---|---|
| Example(Type) | | | | Luminous | Emission | @ |
| (EL measured | Waiting | Voltage | Luminance | Efficiency | Peak | 20 mA/cm²) |
| @ 20 mA/cm²) | Time | (V) | (cd/m²) | (cd/A) | (nm) | (Hrs) |
| 1(Comparative) | 60 | 15.3 | 667 | 3.3 | 528 | 82 |
| 2(Comparative) | 22 | 10.1 | 605 | 3.0 | 528 | 137 |
| 3(Comparative) | 0.5 | 7.3 | 569 | 2.9 | 524 | 203 |

It is evident from Table 1 that longer substrate waiting time in the vacuum chamber will result in increased contamination at the anode surface causing higher drive voltage and lower operational stability for the OLEDs.

### Example 4

### Comparative

A conventional OLED was constructed as the same as that in Example 1 with the same substrate waiting time (60 hours), However the environmental conditions, such as the partial pressures of different species in the vacuum chamber, were not necessarily the same.

This conventional OLED requires a drive voltage of about 9.9 V to pass 20 mA/cm². Under this test condition, the device has a luminance of 593 cd/m², and a luminous efficiency of about 3.0 cd/A. Its emission peak is at 528 nm. The operational stability was measured as T₈₀(70° C.@20 mA/cm²) which is about 140 hours. The EL performance data are summarized in Table 2.

### Example 5

An OLED was constructed as the same as that in Example 4 with the same substrate waiting time (60 hours) and under the same environmental conditions, except that a 0.2 nm-thick contaminant-scavenging layer, F₄-TCNQ layer, was deposited on top of the anode after the substrate waiting time and immediately before the formation of the organic EL unit. The reduction potential of F₄-TCNQ was measured as about 0.64 V vs. SCE in the 1:1 MeCN/MePh organic solvent system.

This OLED requires a drive voltage of about 7.4 V to pass 20 mA/cm². Under this test condition, the device has a luminance of 542 cd/m², and a luminous efficiency of about 2.7 cd/A. Its emission peak is at 524 nm. The operational stability was measured as T₈₀(70° C.@20 mA/cm²) which is longer than 200 hours. The EL performance data are summarized in Table 2.

TABLE 2

| | | | | | | | T₈₀(70° C. |
|---|---|---|---|---|---|---|---|
| Example(Type) | Waiting | With | | | Luminous | Emission | @ |
| (EL measured | Time | CSL* | Voltage | Luminance | Efficiency | Peak | 20 mA/cm²) |
| @ 20 mA/cm²) | (Hrs) | (nm) | (V) | (cd/m²) | (cd/A) | (nm) | (Hrs) |
| 4(Comparative) | 60 | 0 | 9.9 | 593 | 3.0 | 528 | 140 |
| 5 | 60 | 0.2 | 7.4 | 542 | 2.7 | 524 | >200 |

*CSL: Contaminant-Scavenging Layer

It is evident that a 0.2 nm-thick F₄-TCNQ layer as a contaminant-scavenging layer can effectively oxidize the contaminants on the anode surface, a normal drive voltage and operational stability are resumed.

### Example 6

### Comparative

A conventional OLED was constructed as the same as that in Example 1 except that the substrate was exposed to a different vacuum environment which is described as the following:

After about 30 min's substrate waiting time in the deposition chamber with a vacuum pressure about 4.7×10⁻⁵ Torr, an Alq source in the chamber was intentionally heated for outgassing and pre-evaporated until a thickness monitor reached about 50 nm with all the shutters being closed, which means that there was no direct organic deposition onto the substrate because the chamber space was filled with organic species. It is expected that the anode surface was contaminated by the outgassing and pre-evaporation processes. After the processes, the substrate was sitting in the deposition chamber for about 10 min before an organic EL unit was started to form on the anode. The formation of the organic EL unit and the cathode were described in Example 1.

This conventional OLED requires a drive voltage of about 7.4 V to pass 20 mA/cm². Under this test condition, the device has a luminance of 481 cd/m², and a luminous efficiency of about 2.4 cd/A. Its emission peak is at 528 nm. The operational stability was measured as T₉₀(RT@20 mA/cm²) (i.e. a time at which the luminance retains 90% of its initial value after being operated at room temperature and at 20 mA/cm²). Its T₉₀(RT@20 mA/cm²) is about 250 hours. The EL performance data are summarized in Table 3.

### Example 7

An OLED was constructed as the same as that in Example 6 with the same substrate waiting time and under the same environmental conditions, except that a 0.4 nm-thick contaminant-scavenging layer, F₄-TCNQ layer, was deposited on top of the anode after the substrate was exposed to the outgassing and pre-evaporation vacuum conditions and immediately before the formation of the organic EL unit.

This OLED requires a drive voltage of about 6.2 V to pass 20 mA/cm². Under this test condition, the device has a luminance of 513 cd/m², and a luminous efficiency of about 2.6 cd/A. Its emission peak is at 524 nm. The operational stability was measured as T₉₀(RT@20 mA/cm²) which is longer than 350 hours. The EL performance data are summarized in Table 3.

TABLE 3

| | Exposed to | | | | | | T₉₀(RT |
|---|---|---|---|---|---|---|---|
| Example(Type) | Organic | With | | | Luminous | Emission | @ |
| (EL measured | Outgassing | CSL* | Voltage | Lum. | Efficiency | Peak | 20 mA/cm²) |
| @ 20 mA/cm²) | Environment | (nm) | (V) | (cd/m²) | (cd/A) | (nm) | (Hrs) |
| 6(Comparative) | Yes | 0 | 7.4 | 481 | 2.4 | 528 | 250 |
| 7 | Yes | 0.4 | 6.2 | 513 | 2.6 | 524 | >350 |

*CSL: Contaminant-Scavenging Layer

It is evident that a 0.4 nm-thick F₄-TCNQ layer as a contaminant-scavenging layer can effectively oxidize the contaminants on the anode surface, and a normal drive voltage and operational stability are resumed.

### Example 8

### Comparative

A conventional OLED was constructed as the same as that in Example 1 except that the substrate was exposed to a different vacuum environment which is described as following:

After about 3 hours' substrate waiting time in the deposition chamber with a vacuum pressure about 9.0×10⁻⁶ Torr, an Mg source in the chamber was intentionally heated for outgassing and pre-evaporated until a thickness monitor reached about 10 nm with all the shutters being closed, which means that there was no direct metal deposition onto the substrate because the chamber space was filled with some organic and metal species. It is expected that the anode surface was contaminated by the outgassing and pre-evaporation processes. After the processes, the substrate was sitting in the deposition chamber for about 10 min before an organic EL unit was started to form on the anode. The formation of the organic EL unit and the cathode were described in Example 1.

This conventional OLED requires a drive voltage of more than 24 V to pass 20 mA/cm². Under this test condition, the device has a luminance of about 200 cd/m², and a luminous efficiency of about 1.2 cd/A. Its emission peak is at 526 nm. The operational stability was measured as T₅₀(RT@80 mA/cm²) (i.e. an operational lifetime at which the luminance retains 50% of its initial value after being operated at room temperature and at 80 mA/cm²). Its T₅₀(RT@80 mA/cm²) is less than 90 hours. The EL performance data are summarized in Table 4.

### Example 9

An OLED was constructed as the same as that in Example 8 with the same substrate waiting time and under the same environmental conditions, except that 1) a 0.5 nm-thick contaminant-scavenging layer, including hexanitrile hexaazatriphenylene, was deposited on top of the anode after the substrate was exposed to the outgassing and pre-evaporation vacuum conditions and immediately before the formation of the organic EL unit; and 2) the thickness of the HTL (NPB layer) in the organic EL unit was changed from 75 nm to 74.5 nm. The reduction potential of hexanitrile hexaazatriphenylene was measured as −0.08 V vs. SCE in the 1:1 MeCN/MePh organic solvent system.

This OLED requires a drive voltage of about 9.8 V to pass 20 mA/cm². Under this test condition, the device has a luminance of 692 cd/m², and a luminous efficiency of about 3.5 cd/A. Its emission peak is at 526 nm. The operational lifetime T₅₀(RT@80 mA/cm²) is longer than 250 hours. The EL performance data are summarized in Table 4.

### Example 10

An OLED was constructed as the same as that in Example 8 with the same substrate waiting time and under the same environmental conditions, except that 1) a 2 nm-thick contaminant-scavenging layer, including hexanitrile hexaazatriphenylene, was deposited on top of the anode after the substrate was exposed to the outgassing and pre-evaporation vacuum conditions and immediately before the formation of the organic EL unit; and 2) the thickness of the HTL (NPB layer) in the organic EL unit was changed from 75 nm to 73 nm.

This OLED requires a drive voltage of about 7.3 V to pass 20 mA/cm². Under this test condition, the device has a luminance of 581 cd/m², and a luminous efficiency of about 2.9 cd/A. Its emission peak is at 526 nm. The operational lifetime T₅₀(RT@80 mA/cm²) is longer than 300 hours. The EL performance data are summarized in Table 4.

### Example 11

An OLED was constructed as the same as that in Example 8 with the same substrate waiting time and under the same environmental conditions, except that 1) a 10 nm-thick contaminant-scavenging layer, including hexanitrile hexaazatriphenylene, was deposited on top of the anode after the substrate was exposed to the outgassing and pre-evaporation vacuum conditions and immediately before the formation of the organic EL unit; and 2) the thickness of the HTL (NPB layer) in the organic EL unit was changed from 75 nm to 65 nm.

This OLED requires a drive voltage of about 6.1 V to pass 20 mA/cm². Under this test condition, the device has a luminance of 504 cd/m², and a luminous efficiency of about 2.5 cd/A. Its emission peak is at 526 nm. The operational lifetime T₅₀(RT@80 mA/cm²) is longer than 350 hours. The EL performance data are summarized in Table 4.

TABLE 4

| | Exposed to | | | | | | T₅₀(RT |
|---|---|---|---|---|---|---|---|
| Example(Type) | Metal | With | | | Luminous | Emission | @ |
| (EL measured | Outgassing | CSL* | Voltage | Lum. | Efficiency | Peak | 80 mA/cm²) |
| @ 20 mA/cm²) | Environment | (nm) | (V) | (cd/m²) | (cd/A) | (nm) | (Hrs) |
| 8(Comparative) | Yes | 0 | >24 | ~200 | ~1.2 | 526 | <90 |
| 9 | Yes | 0.5 | 9.8 | 692 | 3.5 | 526 | >250 |
| 10 | Yes | 2 | 7.3 | 581 | 2.9 | 526 | >300 |
| 11 | Yes | 10 | 6.1 | 504 | 2.5 | 526 | >350 |

*CSL: Contaminant-Scavenging Layer

It is further evident that a hexanitrile hexaazatriphenylene layer with different thickness as a contaminant-scavenging layer can also effectively oxidize the contaminants on the anode surface and reduce the drive voltage while improving operational stability. Moreover, with the increasing thickness of the contaminant-scavenging layer, from 0.5 nm to 10 nm, the OLED can have decreasing drive voltage and increasing operational lifetime. When the thickness of the hexanitrile hexaazatriphenylene layer is about 10 nm, the EL performance of the OLED is believed to resume to a normal operating condition. As for the lower luminance efficiency in a normal OLED, it is believed this is due to a lower hole injection barrier at the anode/organic interface resulting in a lower electrical field across the LEL. When the thickness of the hexanitrile hexaazatriphenylene layer is about 10 nm, the EL performance of Example 11 is similar to that of Example 7 having a 0.4 nm-thick F₄-TCNQ as the contaminant-scavenging layer, even though the device in Example 11 was made 10 months later.

### Example 12

### Comparative

A conventional OLED was constructed using the same method as described in Example 1 except that the substrate waiting time is reduced from 60 hours to about 2 hours. After the waiting period, the following layers were deposited in the following sequence:

### 1. EL Unit:

a) an HTL, 90 nm thick, including NPB;

b) a LEL, 30 nm thick, including Alq doped with 1.0 vol % 10-(2-benzothiazolyl)-1,1,7,7-tetramethyl-2,3,6,7-tetrahydro-1H,5H,11H(1)benzopyrano(6,7,8-ij)quinolizin-11-one (C545T); and

c) an ETL, 30 nm thick, including Alq doped with 1.2 vol % lithium.

2. Cathode: approximately 210 nm thick, including MgAg

This conventional OLED requires a drive voltage of about 5.1 V to pass 20 mA/cm². Under this test condition, the device has a luminance of 2110 cd/m², and a luminous efficiency of about 10.6 cd/A. Its emission peak is at 520 nm. The operational lifetime was measured as T₅₀(RT@80 mA/cm²) which is about 350 hours. The EL performance data are summarized in Table 5.

### Example 13

### Comparative

An OLED was constructed as the same as that in Example 12 with the same substrate waiting time (about 2 hours), except that a 5.0 nm-thick HIL, copper phthalocyanine (CuPC) layer, was deposited on top of the anode after the substrate waiting time and immediately before the formation of the organic EL unit.

This OLED requires a drive voltage of about 10.1 V to pass 20 mA/cm². Under this test condition, the device has a luminance of 2685 cd/m², and a luminous efficiency of about 13.4 cd/A. Its emission peak is at 520 nm. The operational lifetime was measured as T₅₀(RT@80 mA/cm²) which is about 200 hours. The EL performance data are summarized in Table 5.

### Example 14

An OLED was constructed as the same as that in Example 12 with the same substrate waiting time (about 2 hours), except that a 0.2 nm-thick contaminant-scavenging layer, F₄-TCNQ layer, was deposited on top of the anode after the substrate waiting time and immediately before the formation of the organic EL unit.

This OLED requires a drive voltage of about 4.6 V to pass 20 mA/cm². Under this test condition, the device has a luminance of 1938 cd/m², and a luminous efficiency of about 9.7 cd/A. Its emission peak is at 520 nm. The operational lifetime was measured as T₅₀(RT@80 mA/cm²) which is about 475 hours. The EL performance data are summarized in Table 5

TABLE 5

| | | | | | | | T₅₀(RT |
|---|---|---|---|---|---|---|---|
| Example(Type) | Waiting | With | | | Luminous | Emission | @ |
| (EL measured @ | Time | CSL* | Voltage | Luminance | Efficiency | Peak | 20 mA/cm²) |
| 20 mA/cm²) | (Hrs) | (nm) | (V) | (cd/m²) | (cd/A) | (nm) | (Hrs) |
| 12(Comparative) | 2 | 6 | 5.1 | 2110 | 10.6 | 520 | ~350 |
| 13(Comparative) | 2 | 0 | 10.1 | 2685 | 13.4 | 520 | ~200 |
| 14 | 2 | 0.2 | 4.6 | 1938 | 9.7 | 520 | ~475 |

*CSL: Contaminant-Scavenging Layer

Since the substrates used in Examples 12-14 had a waiting time of about 2 hours in the deposition chamber, it is believed that the anode on the substrates was contaminated, although the contamination level can not be very severe. The OLED fabricated on the contaminated anode shown in Example 12 does not use any contaminant-scavenging layer to restore the anode condition, and the EL performance data can be used as reference for Examples 13 and 14. The OLED in Example 13 has a conventional HIL in between the anode and the HTL. This HIL does not have contaminant-scavenging property because the insertion of this layer neither decreases the drive voltage nor increases the operational lifetime. It indicates that anode surface contamination can not be cured by a conventional HIL. The OLED in Example 14 has a 0.2 nm-thick F₄-TCNQ layer as a contaminant-scavenging layer in contact with the contaminated anode. It is evident that a 0.2 nm-thick F₄-TCNQ layer as a contaminant-scavenging layer can effectively oxidize the contaminants on the anode surface. As a result, the drive voltage is reduced and the operational lifetime is increased compared with the device in Example 12. As for the lower (high) luminance efficiency in Example 14 (Example 13), it is again believed this is due to a lower (high) hole injection barrier at the anode/organic interface resulting in a lower (high) electrical field across the LEL. Actually, the power efficiency of the device in Example 14 is higher than that of the device in Example 13.

The invention has been described in detail with particular reference to certain preferred embodiments thereof, but it will be understood that variations and modifications can be effected within the spirit and scope of the invention.

### PARTS LIST

100 OLED of prior art
110 substrate
120 oxygen-treated anode
150 organic EL unit
170 cathode
180 voltage/current source
190 electrical conductors
200 OLED of prior art
230 anode buffer layer
300 OLED of present invention
340 contaminant-scavenging layer
400 OLED of present invention
550 organic EL unit
552 hole-transporting layer
553 light-emitting layer
554 electron-transporting layer
650 organic EL unit
651 hole-injecting layer
750 organic EL unit
755 electron-injecting layer

1. A method of forming an OLED, comprising:
a) providing a substrate, which includes one or more anodes, into a vacuum chamber or inert atmosphere environment where such substrate resides for at least 30 min before subsequent processing; deforming an anode over a substrate;
b) forming a contaminant-scavenging layer over the anode(s), wherein the contaminant-scavenging layer includes one or more organic materials, each having an electron-accepting property and a reduction potential greater than −0.1 V vs. a Saturated Calomel Electrode, and wherein the one or more organic materials provide more than 50% by mole ratio of the contaminant-scavenging layer;
c) forming an organic electroluminescent unit over the contaminant-scavenging layer; and
d) forming a cathode over the organic electroluminescent unit.

2. The method according to claim 1 wherein forming the contaminant-scavenging layer including a chemical compound

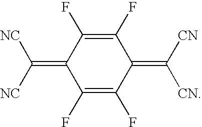

3. The method according to claim 1 wherein forming the contaminant-scavenging layer including a chemical compound 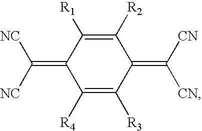
wherein R₁-R₄ represent hydrogen or substituents independently selected from the group including nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, or R₃ and R₄, combine form a ring structure including an aromatic ring, a heteroaromatic ring, or a non-aromatic ring, and each ring is substituted or unsubstituted.

4. The method according to claim 1 wherein forming the contaminant-scavenging layer including a chemical compound 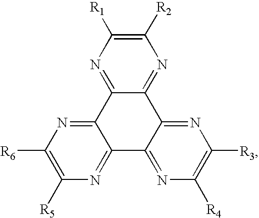
wherein R₁-R₆ represent hydrogen or a substituent independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a non-aromatic ring, and each ring is substituted or unsubstituted.

5. The method according to claim 1 wherein forming the contaminant-scavenging layer including a chemical compound

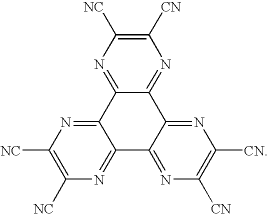

6. A method of forming an OLED, comprising:
a) Providing a substrate, which includes one or more anodes;
b) forming a contaminant-scavenging layer over the anode(s), wherein the contaminant-scavenging layer includes one or more organic materials, each having an electron-accepting property and a reduction potential greater than −0.1 V vs. a Saturated Calomel Electrode, and wherein the one or more organic materials provide more than 50% by mole ratio of the contaminant-scavenging layer;
b) providing the substrate having the contaminant-scavenging layer into a vacuum chamber or inert atmosphere environment where the substrate resides for at least 30 min before subsequent processing;
d) forming an organic electroluminescent unit over the contaminant-scavenging layer; and
e) forming a cathode over the organic electroluminescent unit.

7. The method according to claim 5 wherein forming the contaminant-scavenging layer including a chemical compound

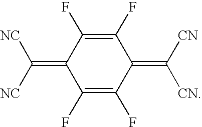

8. The method according to claim 5 wherein forming the contaminant-scavenging layer including a chemical compound 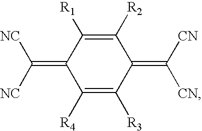
wherein R₁-R₄ represent hydrogen or substituents independently selected from the group including nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, or R₃ and R₄, combine form a ring structure including an aromatic ring, a heteroaromatic ring, or a non-aromatic ring, and each ring is substituted or unsubstituted.

9. The method according to claim 5 wherein forming the contaminant-scavenging layer including a chemical compound 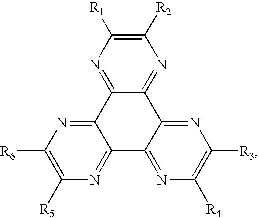
wherein R₁-R₆ represent hydrogen or a substituent independently selected from the group including halo, nitrile (—CN), nitro (—NO₂), sulfonyl (—SO₂R), sulfoxide (—SOR), trifluoromethyl (—CF₃), ester (—CO—OR), amide (—CO—NHR or —CO—NRR′), substituted or unsubstituted aryl, substituted or unsubstituted heteroaryl, and substituted or unsubstituted alkyl, where R and R′ include substituted or unsubstituted alkyl or aryl; or wherein R₁ and R₂, R₃ and R₄, or R₅ and R₆, combine form a ring structure including an aromatic ring, a heteroaromatic ring, or a non-aromatic ring, and each ring is substituted or unsubstituted.

10. The method according to claim 5 wherein forming the contaminant-scavenging layer including a chemical compound [chemical structure]
